(19) United States
(12) Patent Application Publication
(10) Pub. No.: US 2017/0336468 A1
(43) Pub. Date: Nov. 23, 2017

(54) TESTING SYSTEM FOR CIRCUIT BOARD

(71) Applicant: PRIMAX ELECTRONICS LTD., Taipei (TW)

(72) Inventor: PEI-MING CHANG, Taipei (TW)

(21) Appl. No.: 15/226,444

(22) Filed: Aug. 2, 2016

(30) Foreign Application Priority Data
May 20, 2016 (TW) 105115793

(51) Int. Cl. G01R 31/28

(52) U.S. Cl. CPC G01R 31/2801

(57) ABSTRACT

The present invention provides a circuit board testing system, including a computer host and a meter electrically connected to the computer host. A testing program is built in the computer host and displays a testing interface on a screen of the computer host. When a user inputs a circuit board serial number of a circuit board on the testing interface, the testing program displays at least one testing point name corresponding to the circuit board on the testing interface, and when the meter transmits an electrical value of the testing point to the computer host, records the electrical value in a testing result record chart. In the present invention, no jig is needed, and a testing result of a circuit board can be automatically recorded.

### FIELD OF THE INVENTION

The present invention relates to a testing system, and in particular, to a testing system for a circuit board.

### BACKGROUND OF THE INVENTION

In a manufacturing process of an electronic product, a circuit board in the electronic product needs to be tested. Projects for testing are determined according to requirements of a client. Generally, a client would appoint to measure resistance values or voltage values of several areas on a circuit board. Whether the circuit board normally operates is determined according to whether the measured resistance values or voltage values are within a predetermined specification scope.

In the prior art, a factory would first manufacture a test jig for a circuit board to be measured and a predetermined testing point on the circuit board. The jig is used to test the circuit board to obtain testing result data of the circuit board.

However, in actual situation, in the case in which the testing point of the circuit board is determined, it is still possible to temporarily add other testing points. In this case, a new jig needs to be manufactured for the newly added testing points. However, manufacturing of a jig usually takes two to three days, causing a problem that a predetermined testing schedule cannot be met. In this case, an operator needs to measure resistance/voltage values of the newly added testing points by using a meter in a manual manner, and then determines, by using data obtained by manual recording, whether to meet a specification.

A manner of using manual measurement and recording a measurement result not only has bad efficiency but also easily leads to an incorrect record because of negligence of manual operation. Therefore, a novel testing system for a circuit board is required to resolve problems of the prior art.

### SUMMARY OF THE INVENTION

A main objective of the present invention is to provide a circuit board testing system that does not need a jig and can automatically record a resting result of a circuit board.

Preferred embodiments of the present invention provide a circuit board testing system, comprising: a computer host, a circuit board specification table, and a testing program, wherein the circuit board specification table comprises a circuit board serial number, at least one testing point name corresponding to the circuit board serial number and a specification scope corresponding to the testing point name; a screen, electrically connected to the computer host and used to display a testing interface, which is produced by the testing program, wherein the testing interface comprises a circuit board serial number data field; and a meter, electrically connected to the computer host and used to measure an electrical value of at least one testing point on a circuit board, wherein when the circuit board serial number is input to the circuit board serial number data field, the testing interface displays the testing point name corresponding to the circuit board serial number, and when the meter transmits an electrical value of the testing point to the computer host, the testing program records the electrical value on a testing result record chart.

### BRIEF DESCRIPTION OF THE DRAWINGS

FIG. 1 is a schematic diagram of a circuit board testing system of the present invention.

FIG. 2 is a schematic diagram of an embodiment of a circuit board of a testing system of the present invention.

FIG. 3 is a schematic diagram of an embodiment of a testing result record chart of the present invention.

FIGS. 4A to 4D are schematic diagrams of an embodiment of an image of a testing interface in a testing process of the present invention.

### DETAILED DESCRIPTION OF THE PREFERRED EMBODIMENT

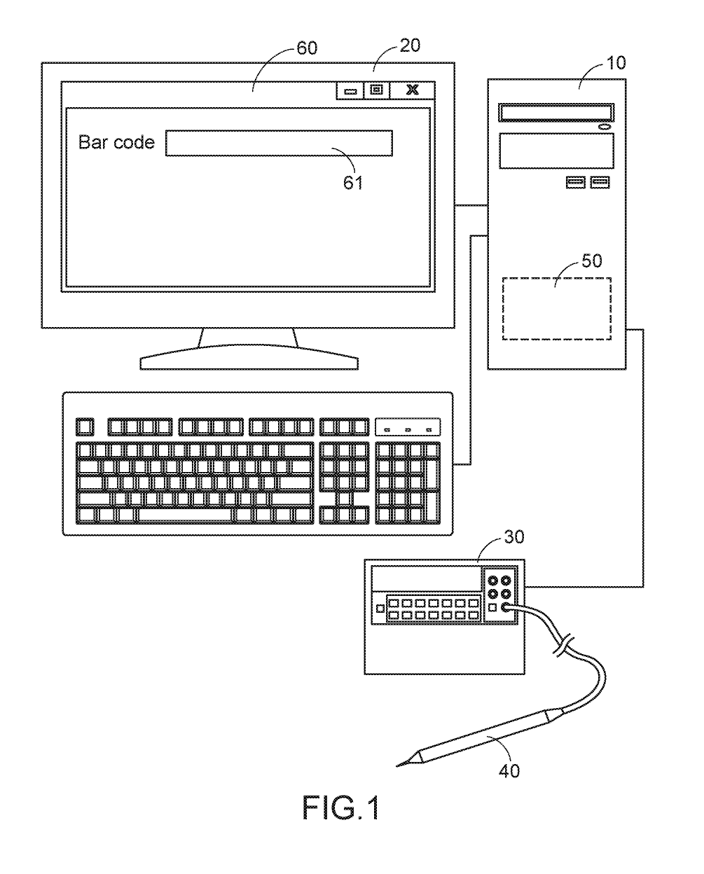

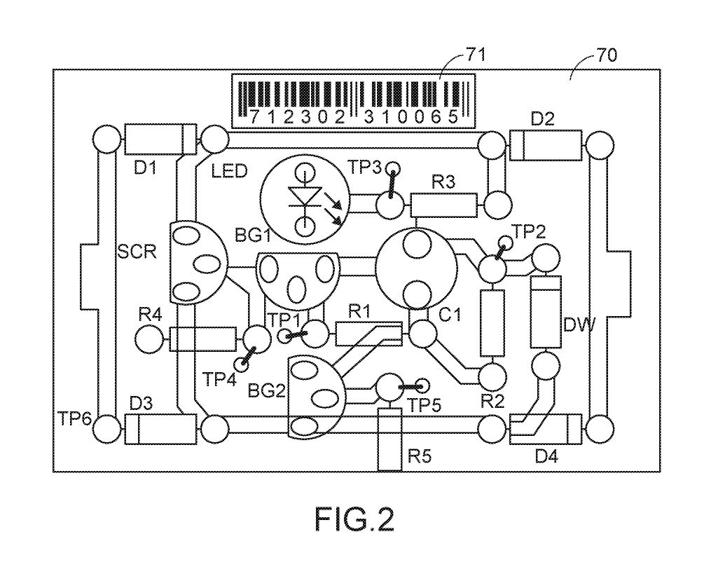

Refer to FIG. 1 and FIG. 2. FIG. 1 is a schematic diagram of a preferred embodiment of a circuit board testing system of the present invention. FIG. 2 is a schematic diagram of an embodiment of a circuit board of a testing system of the present invention. FIG. 1 shows that the system of the present invention comprises a computer host 10, a screen 20, and a meter 30. The computer host 10 is provided with a testing program 50, which displays a testing interface 60 on the screen 20. A probe 40 is connected to the meter 30. A circuit board 70 comprises multiple electronic elements and a circuit layout. In FIG. 2, the circuit board 70 presets six testing points TP1 to TP6. FIG. 2 also shows that a two-dimensional bar code 71 is attached to the circuit board 70 as a reference serial number of the circuit board 70.

The meter 30 is used to measure an electrical value of each testing point, for example, a resistance value or a voltage value. The probe 40 is made in contact with the testing point to display the resistance/voltage value of the testing point on the meter 30. The meter 30 is electrically connected to the computer host 10 so as to transmit the obtained testing point to the computer host 10. The testing interface 60 has a circuit board serial number data field 61.

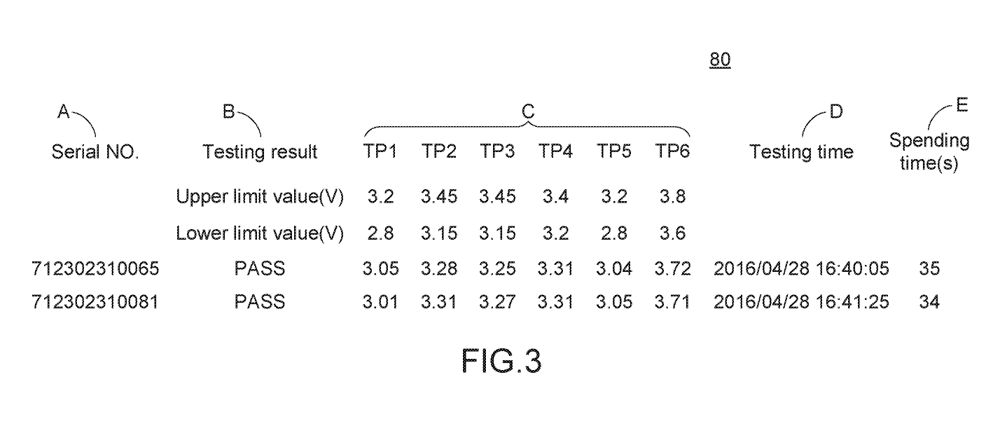

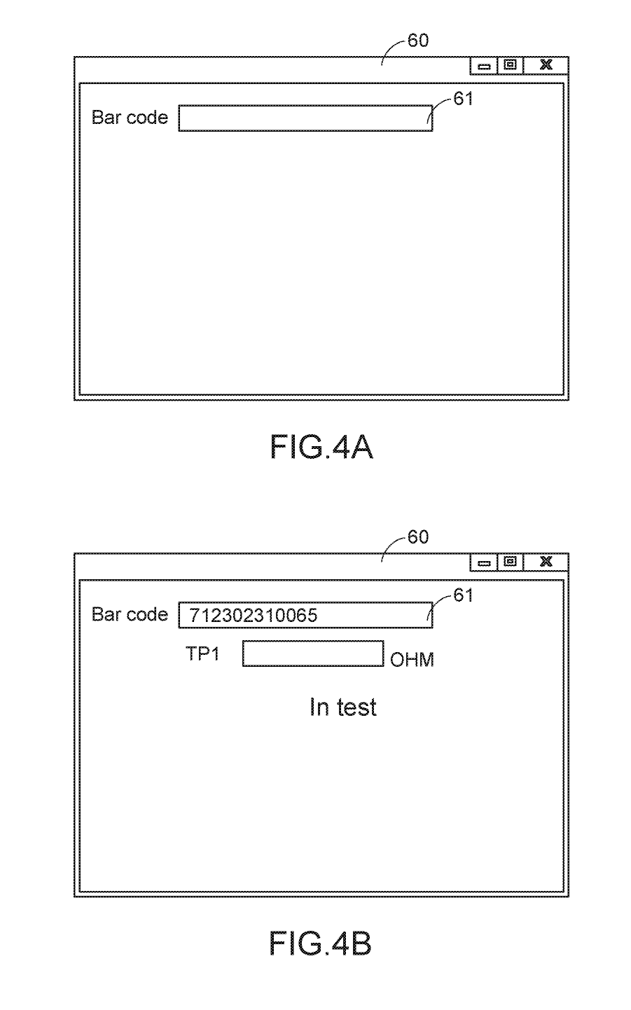

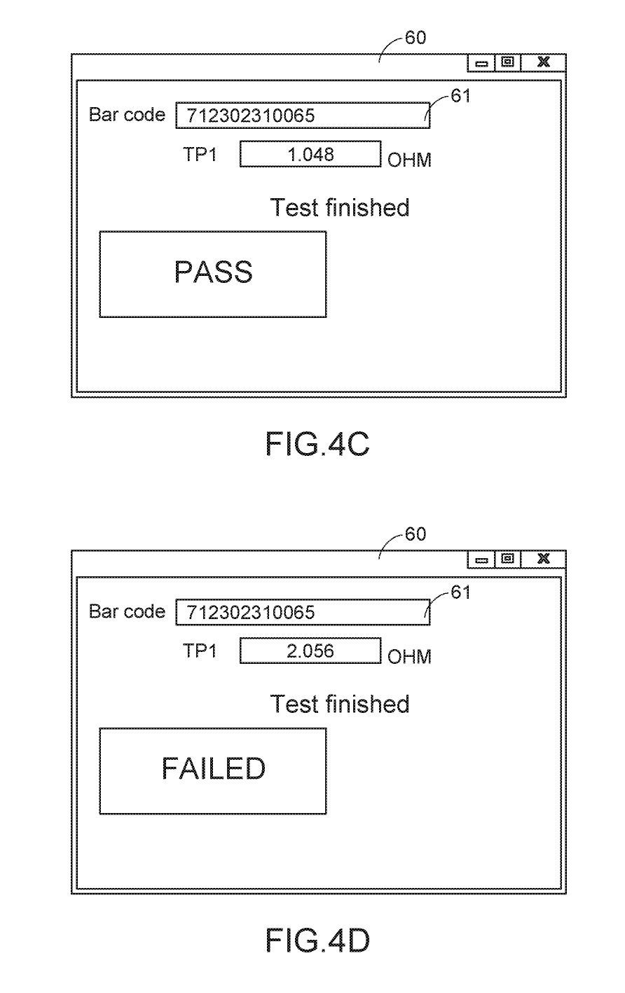

Refer to FIG. 3 and FIGS. 4A to 4D. FIG. 3 shows a schematic diagram of an embodiment of a testing result record chart of the present invention. The testing result record chart 80 of FIG. 3 comprises a serial number column A, a testing result column B, a testing point name column C, testing time D of a circuit board, and spending time column E which is the time spending to measure the circuit board. The serial number column A records a two-dimensional bar code of the circuit board. A testing result column B records a specification scope of a voltage value of each testing point, that is, an upper limit value and a lower limit value of the voltage value. When a value of a testing point falls between the upper limit value and the lower limit value, the testing point passes the test and the test result is “PASS”. If an electrical value is not within the upper limit value and the lower limit value, the testing point does not pass the test and the testing result is “FAIL”. A testing time column D is used to record time at which the circuit board is tested, for future query. A spending time column E records time taken to complete testing of the circuit board, so as to estimate a testing speed.

A method for operating the circuit board testing system of the present invention is described in detail by means of FIGS. 4A to 4D. Firstly, the testing interface 60 displays a circuit board serial number data field for entering a two-dimensional bar code of a circuit board therein, as shown in FIG. 4A. An operator inputs a two-dimensional bar code of the circuit board 70 to the circuit board serial number data field 61. The computer host 10 comprises a circuit board database, in which two-dimensional bar codes of a plurality of to-be-tested circuit boards, a testing point name corresponding to each circuit board, and relevant circuit layout data are stored. The program 50 of the computer host 10 displays a name of a testing point of the circuit board 70 on the testing interface 60 according to the circuit board database and the two-dimensional bar code of the circuit board input by an operator. The testing point TP1 is used as an example in FIG. 4B. Then an operator measures the testing point TP1 displayed by the testing interface 60. That is, an operator makes the probe 40 of the meter 30 to be in contact with the testing point TP1 of the circuit board 70, thereby obtaining an electrical value of the testing point TP1, for example, a voltage value. The voltage value is transmitted to the computer host 10 by using the meter 30. The testing program 50 determines whether the electrical value transmitted by the meter 30 falls within the specification scope. In this determining process, the testing interface 60 displays a message of “in test” and provides a current test progress message to an operator. It should be noted that in a preferred embodiment, the program 50 starts timing when an operator inputs the two-dimensional bar code of the circuit board, and if an electrical value of a testing point transmitted by the meter 30 is not received within a predetermined duration, the program 50 displays a message of “FAIL”. Setting of timing aims at that an operator does not wait around but immediately discover a problem when the meter cannot measure a electrical value of a testing point, for example, because of bad welding, a testing point does not conduct with a circuit of the circuit board.

When the voltage value of the testing point TP1 falls within the specification scope, the testing program 50 displays the voltage value of the testing point TP1 on the testing interface 60 and a message of “PASS”, as shown in FIG. 4C. Certainly, if the voltage value of the resting point TP1 does not fall within the specification scope, the testing program 50 displays a message of “FAIL”, as shown in FIG. 4D. As the foregoing description about FIG. 3, in a test process, the testing program 50 records the two-dimensional bar code of the tested circuit board 70 in the column A of the testing result record chart 80 and records the voltage value of the testing point TP1 in the column C, and records test time of the circuit board 70 and time taken by this test. Test flows of other testing points of the circuit board 70 are the same as a test flow of the testing point TP1 and are not described in detail herein.

In other words, in a test process, an operator only needs to input the two-dimensional bar code of the circuit board on the testing interface, and then learns a name of a to-be-tested testing point from the testing interface. Then the operator only needs to make the probe of the meter to be in contact with a testing point, and the meter can measure an electrical value of the testing point and transmit the electrical value to the computer host. The testing program of the computer host can actively record the electrical value of the testing point and automatically determine whether to pass a test. In addition, the program also actively records an electrical value of each testing point, a test result, test time, and taken time. That is, in the case in which no jig is needed, an operator only needs to input the two-dimensional bar code of the circuit board and measures testing point data according to information displayed on the testing interface, that is, the program may actively produce the testing result record chart but does not manually determine whether to pass a test and record a relevant electrical value. Therefore, efficiency for testing the circuit board is improved.

The above descriptions are merely preferred embodiments of the present invention and are not used to limit the claims of the present invention. Therefore, any other equivalent change or modification accomplished without departing from the spirit disclosed in the present invention shall fall within the claims.

What is claimed is:

1. A circuit board testing system, comprising:
a computer host, comprising a circuit board specification table and a testing program, wherein the circuit board specification table comprises a circuit board serial number, at least one testing point name corresponding to the circuit board serial number and a specification scope corresponding to the testing point name;
a screen, electrically connected to the computer host and used to display a testing interface, which is produced by the testing program, wherein the testing interface comprises a circuit board serial number data field; and
a meter, electrically connected to the computer host and used to measure an electrical value of at least one testing point on a circuit board, wherein when the circuit board serial number is input to the circuit board serial number data field, the testing interface displays the testing point name corresponding to the circuit board serial number, and when the meter transmits an electrical value of the testing point to the computer host, the testing program records the electrical value on a testing result record chart.

2. The circuit board testing system according to claim 1, wherein the electrical value is a resistance value or a voltage value.

3. The circuit board testing system according to claim 1, wherein after receiving the circuit board serial number, the testing program displays the testing point name on the testing interface.

4. The circuit board testing system according to claim 1, wherein the testing program starts timing for a predetermined duration when the circuit board serial number is input to the circuit board serial number data field, when not receiving the electrical value of the testing point transmitted by the meter within the predetermined time duration, the testing program displays a test failure message on the testing interface.

5. The circuit board testing system according to claim 1, wherein the testing result record chart further comprises recording the circuit board serial number, the at least one testing point, a testing result of the at least one testing point, and testing time of the at least one testing point.

6. The circuit board testing system according to claim 5, wherein the testing result is passing a test or failing a test.

7. The circuit board testing system according to claim 6, wherein the testing program displays a test pass message on the testing interface and records the test pass message within the testing result record chart when the electrical value of the testing point transmitted by the meter is located within the specification scope, and displays a test fail message on the testing interface and records the test fail message within the testing result record chart when the electrical value of the testing point transmitted by the meter is not within the specification scope.

8. The circuit board testing system according to claim 1, wherein when receiving the electrical value of the testing point transmitted by the meter, the testing program displays the electrical value on the testing interface.

9. The circuit board testing system according to claim 1, wherein the circuit board serial number is a two-dimensional bar code.
